(19) United States
(12) Patent Application Publication
(10) Pub. No.: US 2020/0361052 A1
(43) Pub. Date: Nov. 19, 2020

(54) PLANARIZATION ENDPOINT DETERMINATION

(71) Applicant: Micron Technology, Inc., Boise, ID (US)

(72) Inventor: James A. Bresson, Nampa, ID (US)

(21) Appl. No.: 16/414,071

(22) Filed: May 16, 2019

(51) Int. Cl. B24B 37/013; H01L 21/306; B24B 49/00; B24B 49/12; B24B 49/08; B24B 37/20

(52) U.S. Cl. CPC B24B 37/013; H01L 21/30625; B24B 37/205; B24B 49/12; B24B 49/08; B24B 49/003

(57) ABSTRACT

A planarization process can be performed on a moving structure by moving a planarizing pad against the moving structure. A liquid and a gas can be injected into a flow cell integrated in the moving pad to produce a two-phase liquid-gas flow in the flow cell while a surface of the moving structure contacts the two-phase liquid-gas flow. An endpoint of the planarization process can be determined by determining that a characteristic of the two-phase liquid-gas flow changes to a predetermined characteristic.

### TECHNICAL FIELD

The present disclosure relates generally to semiconductor processing, and, more particularly, to determining endpoints of planarization processes such as chemical-mechanical planarization (CMP).

### BACKGROUND

Semiconductor processing that can be used to fabricate integrated circuit devices, memory devices, microelectromechanical devices (MEMS), and the like can involve forming various structures (e.g., transistors, capacitors, diodes, etc.) that can include conducting, semiconducting, dielectric, and insulting materials on a substrate, such as a semiconductor. During fabrication, the formed structures can be subjected to planarization or polishing at various stages.

Planarization processes, such as chemical-mechanical planarization processes, which also may be referred to as chemical-mechanical polishing (CMP), can be abrasive techniques that can include the use of a combination of chemical and mechanical agents to planarize, or otherwise remove material from, a structure during fabrication. A moving (e.g., rotating) planarizing or polishing pad (e.g., planarizing pad) can be used in conjunction with chemical solutions and abrasives to mechanically remove material from a structure. Abrasives can be present as a slurry, i.e., combined with the chemical solution, or can be fixed within the planarizing pad itself.

### BRIEF DESCRIPTION OF THE DRAWINGS

FIG. 1A illustrates a planarizing apparatus in accordance with a number of embodiments of the present disclosure.

FIG. 1B illustrates an example of a structure being planarized by a planarizing pad in accordance with a number of embodiments of the present disclosure.

FIG. 2 is a cross-sectional view of a portion of a CMP system in accordance with a number of embodiments of the present disclosure.

FIG. 3 is a cross-sectional view of a portion of a CMP system in accordance with a number of embodiments of the present disclosure.

FIG. 4 illustrates an example of a two-phase liquid-gas flow under hydrophilic and hydrophobic conditions in accordance with a number of embodiments of the present disclosure.

FIG. 5A illustrates a structure moving over a flow cell that is integrated to a planarizing pad during a CMP process in accordance with a number of embodiments of the present disclosure.

FIG. 5B is a cross-section viewed along line 5B-5B of FIG. 5A in accordance with a number of embodiments of the present disclosure.

FIG. 6A illustrates a flow cell in a planarizing pad in accordance with a number of embodiments of the present disclosure.

FIG. 6B is a cross-sectional view viewed along line 6B-6B of FIG. 6A in accordance with a number of embodiments of the present disclosure.

FIG. 7 is a cross-section of a planarizing pad having a flow cell with a group of flow channels having different cross-sectional shapes in accordance with a number of embodiments of the present disclosure.

### DETAILED DESCRIPTION

Various planarization processes, such as chemical-mechanical planarization (CMP) processes, can involve determining a process endpoint. For example, the endpoint can refer to the point at which the surface of a structure reaches a particular (e.g., desired) level of planarization, such as when the surface is polished to a particular finish, and/or when a particular material is exposed by the removal of another material that overlays the particular material (e.g., a film transition). The planarization process can be stopped or modified in response to determining the endpoint. In various examples, a CMP process that is stopped or modified in response to the exposure of an underlying material can be referred to as a stop-on material process. For example, a stop-on nitride process involves ending the CMP process when a material that covers an underlying nitride is removed and exposes the nitride.

One previous approach for determining a planarization endpoint involves removing an object (e.g., a wafer or a structure) from the CMP apparatus and measuring a change in thickness of the object. However, interrupting a CMP process to remove the object can reduce CMP processing throughput and can cause damage to the object. Another endpoint determination approach involves using an estimated polishing rate and can be based upon the polishing rate of the materials used to form an object. However, this approach is a less accurate method for determining endpoints due to differences in polishing rates of various materials and object-to-object non-uniformity.

Another endpoint determination approach utilizes the motor current of a motor that moves the object and/or the motor current of a motor that moves the planarizing pad. For example, a change in the motor current can indicate that the endpoint is reached. The change in motor current can be the result of a change in the coefficient of friction between the object and the planarizing pad that can occur at the endpoint. However, motor-currents can be inherently noisy signals due to electrical and/or mechanical noise. Moreover, a change in the motor-current can be difficult to detect in situations in which the friction between the object and the pad is low, such as when the object exerts a low downward force on the pad. For example, the downward force might be kept low to avoid damage to fragile materials/structures and/or a material covered by a relatively thin material.

Embodiments of the present disclosure overcome the problems of previous approaches for determining CMP endpoints, and thereby provide technical advantages over these approaches. In some embodiments, using characteristics of a two-phase liquid-gas flow in contact with a surface of an object can be utilized as an endpoint determination approach. For example, the flow characteristics of a two-phase liquid-gas flowing through a channel can change in response to the wettability of the surface of the object in contact with the two-phase liquid-gas while undergoing CMP. In some embodiments, monitoring changes of the two-phase liquid-gas flow will provide a signal that can be utilized for endpoint determination.

In some embodiments, the endpoint can be determined by injecting liquid and gas between the surface of an object being planarized and the polishing pad to produce a two-phase liquid-gas flow. A flow cell integrated in the polishing pad detects changes to the two-phase liquid-gas flow. two-An endpoint of the planarization process can be determined by changes in the characteristics (e.g., wettability of a surface) of the two-phase liquid-gas flow and comparing these changed characteristics to predetermined characteristics.

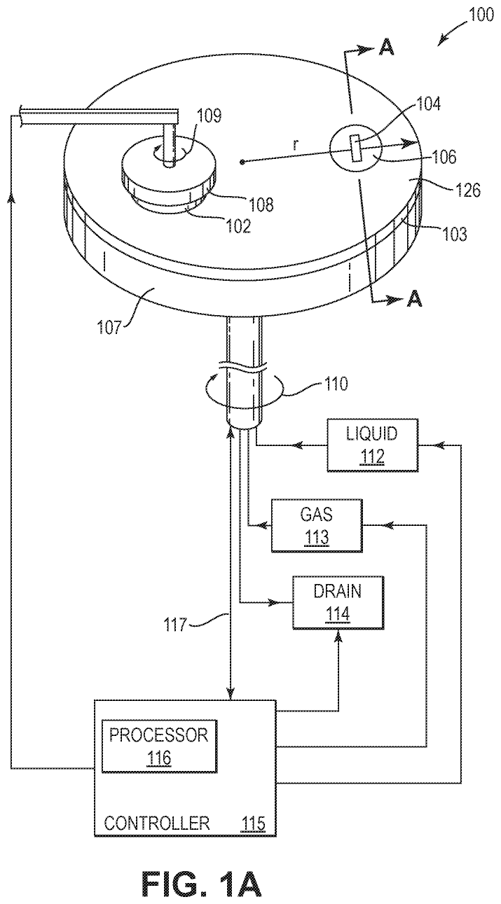

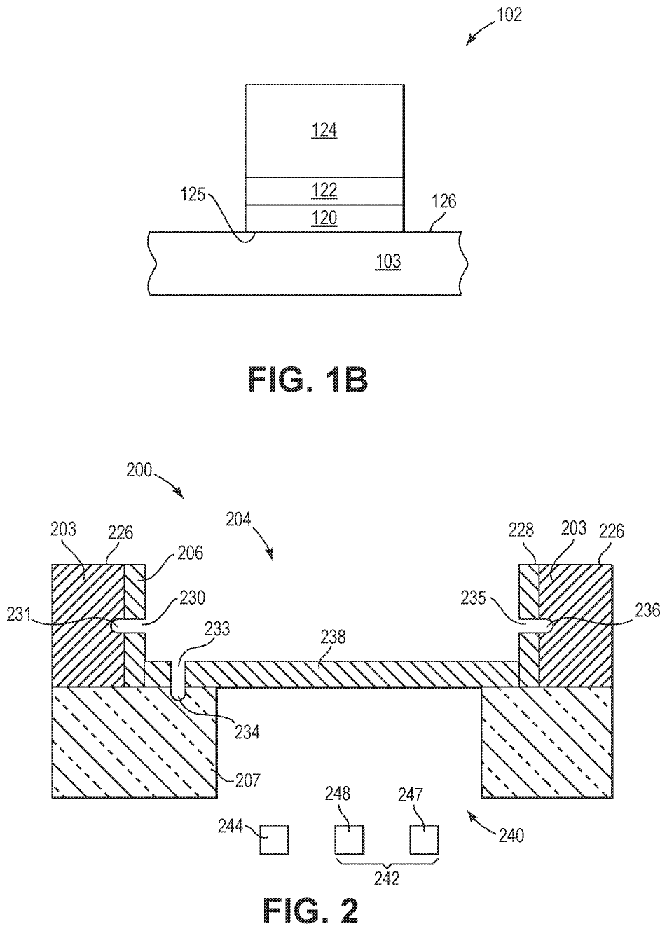

FIG. 1A illustrates a planarizing apparatus, such as a CMP system 100, in accordance with a number of embodiments of the present disclosure. CMP system 100 can determine an endpoint of a CMP process performed on an object, such as a structure 102 (e.g., a semiconductor wafer), as the object moves (e.g., rotates) against a moving (e.g., rotating) planarizing pad 103 during the CMP process.

CMP system 100 can determine whether the endpoint is reached by determining whether the wettability of the surface of structure 102, rotating against planarizing pad 103, changes during the CMP process. CMP system 100 can determine whether the endpoint is reached based on a flow characteristic of a two-phase liquid-gas flow through a channel 104 (e.g., capillary) of a flow cell 106.

For example, CMP system 100 can determine whether the wettability of the surface of structure 102 changes by determining whether the flow characteristic of the two-phase liquid-gas flow changes while flow cell 106 is carried by planarizing pad 103 and while the surface of structure 102 moves in contact with the two-phase liquid-gas flow. Channel 104 can extend in a direction that can be perpendicular to the radius r of planarizing pad 103. However, the present disclosure is not so limited, and channel 104 can extend in the direction of (e.g., can be parallel to) the radius r or can be at an angles, between 90 degrees (e.g., perpendicular) and zero (0) degrees (e.g., parallel), to the radius r.

In various instances, channel 104 can be a spiral channel that can spiral inwards from an outer radius of flow cell 106 toward the center of flow cell 106. For example, the two-phase liquid-gas flow can spiral inward or outward through the spiral channel.

In some embodiments, the two-phase liquid-gas flow can be a two-phase water-air flow. For example, the water is in the liquid state and can be deionized (DI) water. However, the disclosure is not so limited. For example, the gas can be nitrogen (N₂), oxygen (O₂), carbon dioxide (CO₂), argon (Ar), and/or helium (He). In various examples, the liquid can be a mixture of water and ethanol, isopropanol, butanol, and/or various surfactants. As such, in some instances, the two-phase liquid-gas flow can be an aqueous two-phase liquid-gas flow.

In various examples, an abrasive slurry applied to planarizing pad 103 can be non-aqueous (e.g., oil based). In such examples, the liquid component of two-phase liquid-gas flow might not be water based. For example, the liquid component might be oil based or some other liquid that is compatible with the non-aqueous slurry.

As illustrated in FIG. 1A, CMP system 100 has movable platen, such as a circular rotary platen 107. Planarizing pad 103 is over (e.g. on) platen 107. A moving carrier 108 can be configured to rotate structure 102, in the direction of arrow 109, against (e.g., in direct physical contact with) planarizing pad 103. In some examples, platen 107 and planarizing pad 103 can rotate in the direction of arrow 110 that can be the same direction as arrow 109. However, the present disclosure is not so limited, and structure 102 and platen 107 can rotate in opposite directions. Flow cell 106 can be integrated in planarizing pad 103 and can be carried by planarizing pad 103 as planarizing pad 103 moves (e.g., rotates).

A liquid supply 112, such a DI water supply, and a gas (e.g., air) supply 113 can be coupled to channel 104 to respectively supply liquid and gas to channel 104. A drain 114 can be fluidly coupled to channel 104 to receive a two-phase liquid-gas flow from channel 104. For example, liquid supply 112, gas supply 113, and drain 114 can be fluidly coupled to channel 104 via respective rotary unions (not shown) and respective flow lines (not shown in FIG. 1A) in planarizing pad 103 and/or platen 107.

CMP system 100 can have a controller 115 that can have a processor 116. For example, processor 116 can execute instructions (e.g., firmware) that can cause controller 115 to cause CMP system 100 to perform the various operations disclosed herein. Controller 115 can be coupled to liquid supply 112, gas supply 113, and drain 114 to control the operation of liquid supply 112, gas supply 113, and drain 114. For example, liquid supply 112, gas supply 113, and drain 114 can be motorized syringe pumps that can be controlled by controller 115.

Controller 115 can be coupled to control the operation of carrier 108, such as the rotational velocity of carrier 108, and thus structure 102. Controller 115 can be coupled to control the downward force that structure 102 exerts on planarizing pad 103. Controller 115 can also be coupled to control the operation of platen 107.

In various instances, controller 115 can be coupled to sensors (not shown in FIG. 1A), via a bidirectional bus 117, that can be located in platen 107. For example, bidirectional bus 117 can be coupled to the sensors by slip rings (not shown). Alternatively, controller 115 can be wirelessly coupled to the sensors. In various other examples, controller 115 can be coupled to stationary sensors that are located remotely to platen 107 (e.g., directly under structure 102 as structure 102 rotates). As described further herein the sensors can be optically and/or acoustically coupled to the two-phase liquid-gas flow in channel 104 to determine (e.g., sense) various characteristics of the flow.

In some examples, as structure 102 rotates against planarizing pad 103 during CMP, abrasive particles in planarizing pad 103 and/or slurry applied to planarizing pad 103 can mechanically remove material from the surface of structure 102, and reactive chemicals applied to planarizing pad 103 can chemically remove the material from structure 102 and/or planarizing pad 103.

FIG. 1B illustrates an example of structure 102 being planarized by planarizing pad 103 in accordance with a number of embodiments of the present disclosure. As shown in FIG. 1B, structure 102 can include a material 120 covering (e.g., in direct physical contact with) a material 122. Material 122 can cover a substrate 124. A surface 125 of structure 102 (e.g., of material 120) can be in direct physical contact with an upper surface 126 of planarizing pad 103. CMP system 100 can determine the endpoint of a CMP process that can remove material 120 from material 122. For example, the endpoint can be reached when the surface 125 is polished to a particular (e.g., desired) finish or when material 120 is removed from material 122 such that surface 125 becomes the surface of material 122 (e.g., during a stop-on-material 122 process).

In various instances, the wettability of the surface 125 can change when the endpoint is reached. For example, the wettability of a polished surface can be different than the wettability of an unpolished surface, and/or the wettability of an exposed surface of material 122 can be different than the wettability of an exposed surface of material 120. As such, CMP system 100 can determine the endpoint by detecting a change in the wettability of surface 125.

The wettability of a surface can be referred to as the ability of the surface to be coated (e.g., wetted) by a liquid in the presence of an immiscible fluid, such as a gas. For example, a surface that has a relatively low wettability by water in the presence of air can be referred to as a hydrophobic surface, whereas a surface that has a relatively high wettability by water in the presence of air can be referred to as a hydrophilic surface. As discussed further herein, the wettability of a surface contacted by a liquid and a gas can be given by a contact angle that can be measured through the liquid at a point where an interface between the water and the gas meets the surface. For example, the higher the contact angle the lower the wettability and vice versa.

FIG. 2 is a cross-sectional view of a portion of CMP system 200 that can be CMP system 100 in accordance with a number of embodiments of the present disclosure. The cross-section in FIG. 2 corresponds to a cross-section viewed along line A-A in FIG. 1A. FIG. 2 illustrates a portion of a planarizing pad 203 that can be planarizing pad 103. Planarizing pad 203 includes a flow cell 206 that can be flow cell 106. Flow cell 206 includes a flow channel 204 that can be flow channel 104 and that can extend into flow cell 206 from an upper surface 228 of flow cell 206. For example, upper surface 228 can be coplanar with an upper surface 226 of planarizing pad 203. Planarizing pad 203 can be on a platen 207 that can be platen 107.

Flow cell 206 can include a liquid injection port 230 that can be fluidly coupled to liquid supply 112 by a flow passage 231 that can, for example, pass through planarizing pad 203 and be fluidly coupled to liquid supply 112 through the respective rotary union described previously. Flow cell 206 can include a gas injection port 233 that can be fluidly coupled to gas supply 113 by a flow passage 234 that can, for example, pass through platen 207 and be fluidly coupled to gas supply 113 through the respective rotary union described previously. Flow cell 206 can include a drain port 235 that can be fluidly coupled to drain 114 by a flow passage 236 that can, for example, pass through planarizing pad 203 and be fluidly coupled to drain 114 through the respective rotary union described previously. Note that liquid injection port 230 and gas injection port 233 form respective inlets to flow channel 204, and drain port 235 forms an outlet of flow channel 204. However, the present disclosure is not limited to the locations of the liquid injection port 230, the gas injection port 233, and/or the drain port 235 illustrated in FIG. 2. For example, in other embodiments, the liquid injection port 230, the gas injection port 233, and/or the drain port 235, can be located in other areas or in other orientations within flow channel 204.

In various examples, flow cell 206 can be transparent to electromagnetic radiation (e.g., light) such that the electromagnetic radiation can pass through a bottom wall 238 of flow cell 206. For instance, the electromagnetic radiation can enter flow passage 204 through bottom wall 238, and the electromagnetic radiation can exit flow passage 204 through bottom wall 238. For example, flow cell 206 can be optically transparent to light such that the light can pass through bottom wall 238. In some examples, flow cell 206 can be fabricated from an optically transparent polymer.

There can be an opening 240 in platen 207 that can expose bottom wall 238 so that a remote (e.g., remote to platen 207), stationary sensing system 242, such as an optical sensing system or an acoustical sensing system, and/or a remote, stationary image capturing device, such as camera 244 (e.g., a charge coupled device (CCD) camera), can access (e.g., optically) flow channel 204 via opening 240 and bottom wall 238. For example, sensing system 242 can include a source 247 and a detector 248. Although shown separately from sensing system 242, camera 244 can be a detector of sensing system 242 in various examples.

Source 247 can be an electromagnetic radiation source, such as a light source (e.g., a laser), and detector 248 can be an electromagnetic radiation detector. In various other examples, source 247 can be an acoustic energy source, and detector 248 can be an acoustic energy detector. Sensor 242 and camera 244 can be activated (e.g., by controller 115) during a portion of the period of revolution of platen 207 when opening 240 is aligned with sensing system 242 and camera 244 and when structure 102 is aligned with flow cell 206, as described further herein.

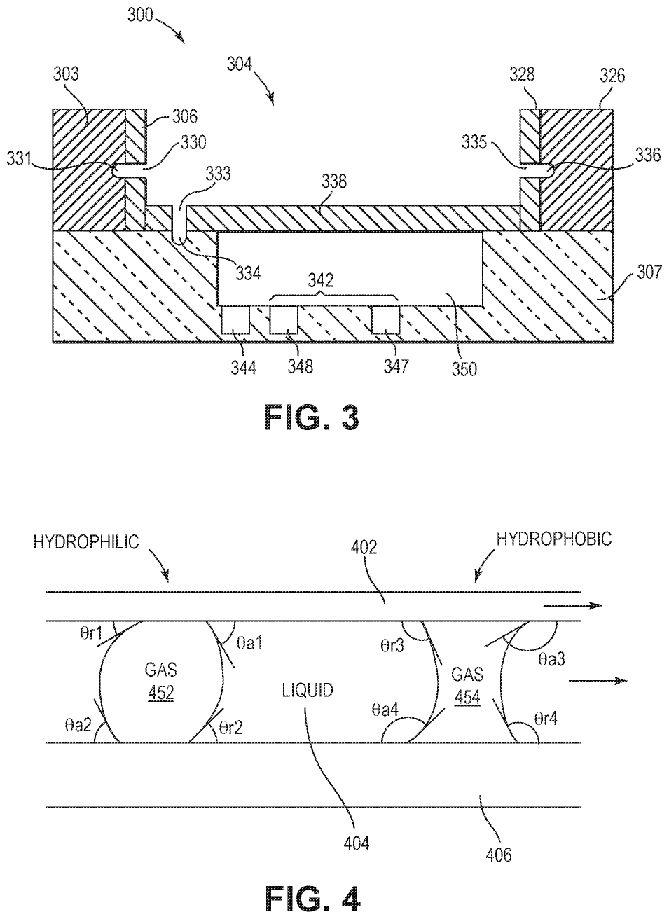

FIG. 3 is a cross-sectional view of a portion of a CMP system 300 that can be CMP system 100 in accordance with a number of embodiments of the present disclosure. The cross-section in FIG. 3 corresponds to a cross-section, viewed along line A-A in FIG. 1A. FIG. 3 illustrates a portion of a planarizing pad 303 that can be planarizing pad 103. Planarizing pad 303 includes a flow cell 306 that can be flow cell 106. Flow cell 306 includes a flow channel 304 that can be flow channel 104 and that can extend into flow cell 306 from an upper surface 328 of flow cell 306. For example, upper surface 328 can be coplanar with an upper surface 326 of planarizing pad 303. Planarizing pad 303 can be on a platen 307 that can be platen 107.

Flow cell 306 can include a liquid injection port 330 that can be fluidly coupled to liquid supply 112 by a flow passage 331 that can, for example, pass through planarizing pad 303 and be fluidly coupled to liquid supply 112 through the respective rotary union described previously. Flow cell 306 can include a gas injection port 333 that can be fluidly coupled to gas supply 113 by a flow passage 334 that can, for example, pass through platen 307 and be fluidly coupled to gas supply 113 through the respective rotary union described previously. Flow cell 306 can include a drain port 335 that can be fluidly coupled to drain 114 by a flow passage 336 that can, for example, pass through planarizing pad 303 and be fluidly coupled to drain 114 through the respective rotary union described previously.

In various examples, flow cell 306 can be transparent to electromagnetic radiation such that the electromagnetic radiation can pass through a bottom wall 338 of flow cell 306. For instance, the electromagnetic radiation can enter flow passage 304 through bottom wall 338, and the electromagnetic radiation can exit flow passage 304 through bottom wall 338. For example, flow cell 306 can be optically transparent to light such that the light can pass through bottom wall 338. In some examples, flow cell 306 can be fabricated from an optically transparent polymer.

There can be an opening 350 in platen 307 that can extend from bottom wall 338 and terminate within platen 307. A sensing system 342, such as an optical sensing system, and/or a camera 344 can be located within platen 307. For example, opening 350 can expose bottom wall 338, and thus flow passage 304, to sensing system 342 and camera 344. As such, opening 350 can provide access to flow passage 304, so sensing system 342 and camera 344 can access flow passage 304 via opening 350.

Sensing system 342 can include a source 347 and a detector 348. In various examples, source 347 can be an electromagnetic radiation source, such as a light source (e.g., a light emitting diode (LED)), and detector 348 can be an electromagnetic radiation detector. Although shown separately from sensing system 342, camera 344 can be a detector of sensing system 342 in various examples. In various other examples, source 347 can be an acoustic energy source, and detector 348 can be an acoustic energy detector. Sensor 342 and camera 344 can be activated (e.g., by controller 115) during a portion of the period of revolution of platen 307 when structure 102 is aligned with flow cell 306, as described further herein.

FIG. 4 illustrates an (e.g., idealized) example of a two-phase liquid-gas flow (e.g., an aqueous two-phase liquid-gas flow) under hydrophilic and hydrophobic conditions in accordance with a number of embodiments of the present disclosure. In FIG. 4, a structure 402, that can be structure 102, can be moving relative to a flow cell 406 that can be flow cell 106. For example, the movement of structure 402 can drive the flow through a channel 404, that can be channel 104, from left to right in FIG. 4. Note that the example of FIG. 4 illustrates the effect of surface wettability on the structure of the two-phase liquid-gas flow.

At the left of FIG. 4, structure 402 and flow cell 406 are hydrophilic. Dynamic contact angles θa1 and θa2 correspond to advancing portions of a gas bubble 452, and dynamic contact angles θr1 and θr2 correspond to receding portions of a gas bubble 452. The dynamic contact angles can be indicative of the wettability of the corresponding surface, with the wettability decreasing with increasing contact angle. Note, for example, that the flow of the liquid and the gas can cause θa1>θa2>θr2>θr1.

At the right of FIG. 4, structure 402 and flow cell 406 are hydrophobic. Dynamic contact angles θa3 and θa4 correspond to advancing portions of a gas bubble 454, and dynamic contact angles θr3 and θr4 correspond to receding portions of a gas bubble 454. Note, for example, that the flow of the liquid and the gas can cause θa3>θa4>θr4>θr3. Also note that the decreased wettability of the hydrophobic surfaces acts to increase the dynamic contact angles compared to the dynamic contact angles for the hydrophilic surfaces. For example, the dynamic contact angles corresponding to the hydrophilic surfaces can be less than 90 degrees, whereas the dynamic contact angles corresponding to the hydrophobic surfaces can be greater than 90 degrees.

Note that the non-limiting example of FIG. 4 illustrates how a two-phase liquid-gas flow can respond to the wettability of the surfaces in contact with the two-phase liquid-gas flow, and thus how the two-phase liquid-gas flow can be used to monitor the wettability of the surfaces in contact with the two-phase liquid-gas flow, such as the surface of structure 402 in contact with the two-phase liquid-gas flow. It should be recognized that although the wettability of the surface of structure 402 in contact with the two-phase liquid-gas flow can transition from hydrophobic to hydrophilic or hydrophilic to hydrophobic during CMP when the endpoint is reached, the wettability of the surface of the flow cell in contact with the two-phase liquid-gas flow can remain unchanged because the surface of the flow cell in contact with the two-phase liquid-gas flow is not being subjected to CMP.

The dynamic contact angles can depend on the capillary number, Ca, of the two-phase liquid-gas flow. The capillary number relates the viscous forces, resulting from the motion of the two-phase liquid-gas flow, to the surface tension forces acting across a liquid-gas interface (e.g., for a two-phase liquid-gas flow). The capillary number is defined as Ca=μV/γ, in which μ is the dynamic viscosity of the liquid, γ the surface tension of the liquid-gas interface, and V is a characteristic velocity of the two-phase liquid-gas flow. For example, V=QA, in which Q is the volumetric flow rate of the two-phase liquid-gas flow through the flow channel and A is the cross-sectional area of the flow channel perpendicular to the two-phase liquid-gas flow.

In some examples, the sensitivity of various flow characteristics of the two-phase liquid-gas flow to a change in the wettability of the surface of structure 402 in contact with the two-phase liquid-gas flow can be modified by adjusting the capillary number. For example, the capillary number can be adjusted so that the various characteristics of the two-phase liquid-gas flow have a relatively a high sensitivity to changes in the wettability of the surface of structure 402 in contact with the two-phase liquid-gas flow.

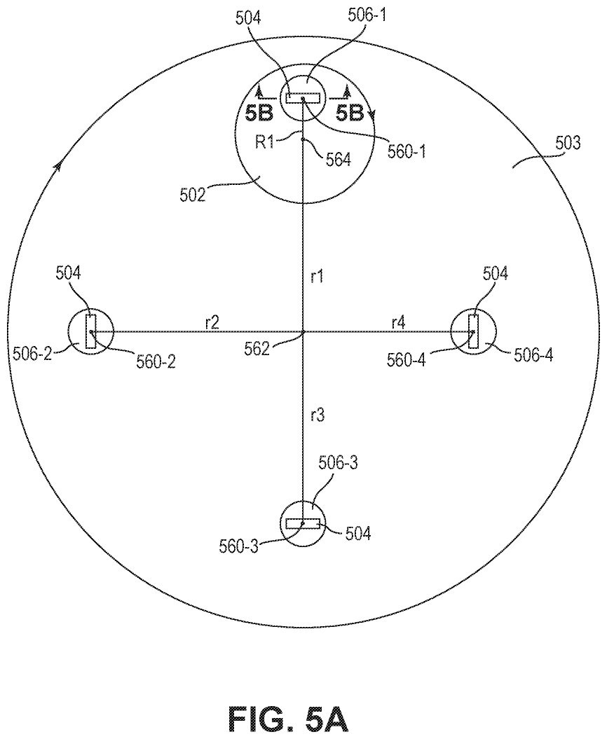

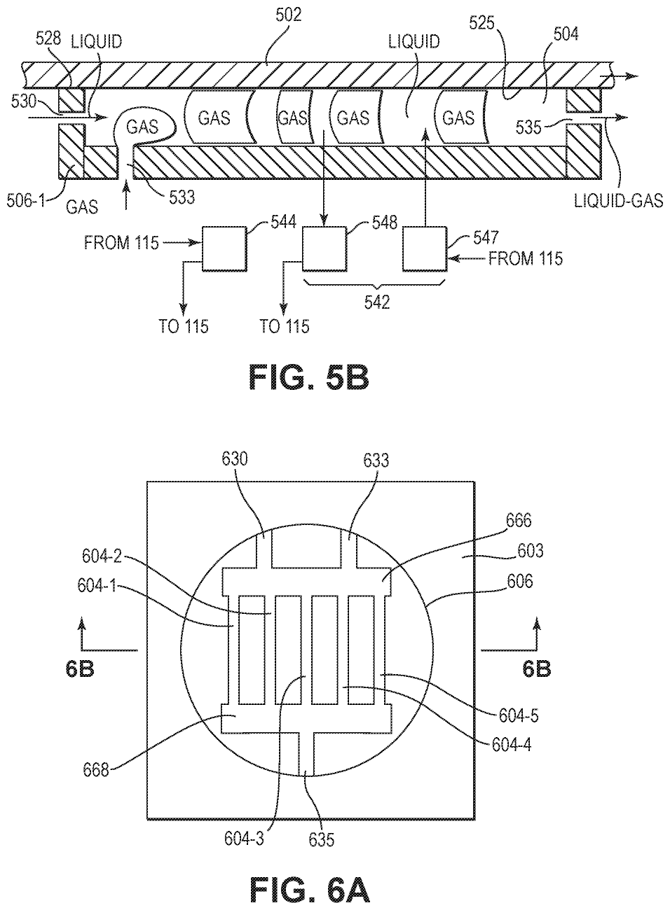

FIG. 5A illustrates a structure 502 moving (e.g., rotating) over a flow cell 506-1 that is integral to a moving (e.g., rotating) planarizing pad 503 during a CMP process in accordance with a number of embodiments of the present disclosure. For example, structure 502 can be structure 102 and planarizing pad 503 can be planarizing pad 103, 203, or 303. Planarizing pad 503 includes additional flow cells 506-2 to 506-4. Each of the flow cells 506-1 to 506-4 can be flow cell 106, 206, 306, or 406 and can include a flow channel 504 that can be flow channel 104, 204, 304, or 404.

The respective centers 560-1 to 560-4 of the respective flow cells 506-1 to 506-4 are respectively at distances (e.g., radii) r1 to r4 from the center 562 of planarizing pad 503. For example, r1>r2>r3>r4. As such, each of the flow cells 506-1 to 506-4 can sweep (e.g., track) a different portion of rotating structure 502. For example, a two-phase liquid-gas flow in each of the respective flow cells 506-1 to 506-4 can sense a respective portion of rotating structure 502 to account for variations in the surface of rotating structure 502 during the CMP process.

Although the respective channels 504 are shown to be perpendicular to the respective radii r1 to r4, the disclosure is not so limited. For example, the respective channels 504 can extend in the directions of (e.g., can be parallel to) the respective radii r1 to r4 or can be at respective angles, between 90 degrees (e.g., perpendicular) and zero (0) degrees (e.g., parallel), to the respective radii r1 to r4. In some examples, channel 504 of flow cell 506-1 can be perpendicular to radius r1; channel 504 of flow cell 506-4 can be parallel to radius r4; channel 504 of flow cell 506-2 can be between 45 to 90 degrees to radius r2; and channel 504 of flow cell 506-3 can be between 0 to 45 degrees to radius r3.

In various instances, the channels 504 can be spiral channels that can spiral inwards from an outer radius of flow cells 506 toward the centers 560 of flow cells 506. For example, the respective two-phase liquid-gas flows can spiral inward or outward through the respective spiral channels. In various other examples, the respective channels 504 can have different widths.

In some instances, for example, the endpoints at different locations on the surface of rotating structure 502 can occur at different times. For example, the planarization of the surface rotating structure 502 can occur at different rates at the different locations. Flow cells 506-1 to 506-4 can be used to determine when the different endpoints occur. As such, in some examples, adjustments can be made in real-time during the planarization process or in subsequent planarization processes, based on when the different endpoints occur, to even out the planarization rate over the surface of rotating structure 502.

In various examples, sensed characteristics of the flows in the respective flow cells 506-1 to 506-4 can be averaged, and the resulting average can be compared to a predetermined characteristic to determine whether the endpoint is reached. In various other examples, such as for a stop-on-material process (e.g., in which the endpoint corresponds to the removal of material 120 in FIG. 1B from material 122 to expose material 122), the endpoint might be determined to be reached when the sensed characteristic of the flow in each of the respective flow cells 506-1 to 506-4 changes to a predetermined characteristic.

FIG. 5B is a cross-section, viewed along line 5B-5B of FIG. 5A, of structure 502 in contact with a two-phase liquid-gas flow in flow channel 504 of flow cell 506-1 in accordance with a number of embodiments of the present disclosure. For example, structure 502 closes flow channel 504 at the upper surface 528 of flow cell 506-1, and flow channel 504 carries two-phase liquid-gas flow while structure 502 closes flow channel 504. Note that the ensuing discussion in conjunction with FIG. 5B can apply to each of the additional flow cells 506-2 to 506-4 when each respective flow cell of the cells 506-2 to 506-4 is aligned with structure 502. Note that the respective flow cells 506-1 to 506-4 can monitor rotating structure 502 during a respective portion of the rotational period of planarizing pad 502. As such, FIG. 5B corresponds to a portion of the rotational period of planarizing pad 502.

In FIG. 5B, liquid (e.g., DI water) from liquid supply 112 and gas (e.g., air) from gas supply 113 are concurrently injected into flow channel 504 respectively through liquid injection port 530 and gas injection port 533, as structure 502 is moving over flow channel 504, to produce a two-phase liquid-gas that exits flow channel 504 through a drain port 535 and into drain 114. For example, structure 502 can close the top of flow channel 504 while structure 502 moves over flow channel 504 in contact with the two-phase liquid-gas flow. The two-phase liquid-gas flow can be driven by a pressure differential between the injection ports and the drain port and by the movement of structure 502 against the two-phase liquid-gas flow. In various examples, controller 115 can activate liquid supply 112, gas supply 113, and drain 114 concurrently in response to flow cell 506-1 aligning with structure 502, as shown in FIG. 5A.

In various instances, liquid injection port 530 can be larger (e.g., much larger) than gas injection port 533. For example, liquid injection port 530 can span the entire height of flow channel 504.

In some examples, the capillary number of the two-phase liquid-gas system in FIG. 5B and/or the ratio of the liquid volumetric flowrate to the gas volumetric flowrate can be adjusted to increase the sensitivity of the two-phase liquid-gas flow to changes in the wettability of surface 525 of structure 502, as described previously.

In various other examples, the volumetric flowrate in the flow channel can be adjusted so that the product of volumetric flowrate and the cross-sectional area of flow channel 504, perpendicular to the flow, is about the same as a tangential velocity Vt of structure 502 at the center 560-1 of flow cell 506-1. For example, Vt=ωR1, in which w is the angular velocity (e.g., rotational velocity) of structure 502 and R1 (see FIG. 5A) is the distance from the center 564 of structure 502 to the center 560-1 of flow cell 506-1.

Various flow characteristics of the two-phase liquid-gas flow can be responsive to, and thus can change in response to, a change in the wettability of surface 525 of structure 502 in contact with the two-phase liquid-gas flow. Non-limiting examples of flow characteristics that can change in response to a change in the wettability of surface 525 can include the reflectivity of the two-phase liquid-gas flow, the refractive index of the two-phase liquid-gas flow, the mean size (e.g., diameter) of the gas bubbles in the two-phase liquid-gas flow, the mean distance between gas bubbles in the two-phase liquid-gas flow, the gas void fraction of the two-phase liquid-gas flow (e.g., the fraction of the flow channel cross-sectional area or the flow channel volume occupied by the gas), and the like. In some examples, the intensity of light scattered by the two-phase liquid-gas flow can change in response to a change in the wettability of surface 525.

The flow characteristics can be sensed by a sensing system 542 that can be sensing system 242 or 342 and/or a camera 544 that can be camera 244 or 344. Sensing system can include a source 547 that can be source 247 or 347 and a detector 548 that can be detector 248 or 348. Although shown separately from sensing system 542, camera 544 can be a detector of sensing system 542 in various examples.

Sensing system 542 and/or camera 544 can be triggered in response to control signals from controller 115. For example, controller 115 can trigger sensing system 542 and/or camera 544 in response to determining that structure 502 is aligned with flow cell 506-1.

In various examples, source 547, or some other source (not shown), can irradiate the two-phase liquid-gas flow with electromagnetic radiation (e.g., light or infrared radiation), and camera 544 can sense the irradiated two-phase liquid-gas flow. Camera 544 can transmit signals, corresponding to the irradiated two-phase liquid-gas flow, to controller 115 so that processor 116 can analyze and/or process the signals. For example, processor 116 can construct images from the signals and can analyze those images to determine the mean size of the gas bubbles in the two-phase liquid-gas flow or the mean distance between gas bubbles. For example, processor 116 can average the size of the gas bubbles in the two-phase liquid-gas flow to determine the mean size and can average the distances between the gas bubbles in the two-phase liquid-gas flow to determine to the mean distance.

Processor 116 can compare the mean size to a predetermined mean size and/or compare the mean distance to a predetermined mean distance to determine whether the wettability of surface 525 has changed, and thus whether the endpoint is reached. For example, processor 116 can determine that the endpoint is reached in response to determining that the mean distance has changed to the predetermined mean distance and/or the mean size has changed to the predetermined mean size. Note that predetermined mean distance and the predetermined mean size can be determined during calibration processes that can involve examining surface 525 to confirm that the predetermined mean distance and the predetermined mean size correspond to the endpoint.

In some examples, source 547 can irradiate the two-phase liquid-gas flow with light that can be reflected, refracted, and/or scattered by the two-phase liquid-gas flow. Detector 548 can detect the reflected, refracted, and/or scattered light and can transmit signals corresponding to the reflected, refracted, and/or scattered light to controller 115. Processor 116 can analyze the signals to determine the reflectivity of the two-phase liquid-gas flow, the refractive index of the two-phase liquid-gas flow, and/or the intensity of the scattered light.

Processor 116 can compare the reflectivity to a predetermined reflectivity, the refractive index to a predetermined refractive index, and/or the intensity of the scattered light to a predetermined intensity to determine whether the wettability of surface 525 has changed, and thus whether the endpoint is reached. For example, processor 116 can determine that the endpoint is reached in response to determining that the reflectivity has changed to the predetermined reflectivity, the refractive index has changed to the predetermined refractive index, and the intensity of the scattered light has changed to the predetermined intensity. Note that the predetermined reflectivity, the predetermined refractive index, and the predetermined intensity can be determined during calibration processes that can involve examining surface 525 to confirm that the predetermined reflectivity, the predetermined refractive index, and the predetermined intensity correspond to the endpoint.

In various examples, the gas void fraction of the two-phase liquid-gas flow can be determined acoustically. For example, source 547 can transmit acoustic energy to the two-phase liquid-gas flow, and the two-phase liquid-gas flow can emit acoustic energy in response to the transmitted acoustic energy. Detector 548 can receive the emitted acoustic energy and can generate a signal, in response to the emitted acoustic energy, that can be indicative of the gas void fraction. Controller 115 can receive the signal from detector 548, and processor 116 can determine the gas void fraction from the signal.

Processor 116 can compare the gas void fraction to a predetermined gas void fraction to determine whether the wettability of surface 525 has changed, and thus whether the endpoint is reached. For example, processor 116 can determine that the endpoint is reached in response to determining that the gas void fraction has changed to the predetermined gas void fraction. Note that the predetermined gas void fraction can be determined during a calibration process that can involve examining surface 525 to confirm that the predetermined gas void fraction corresponds to the endpoint.

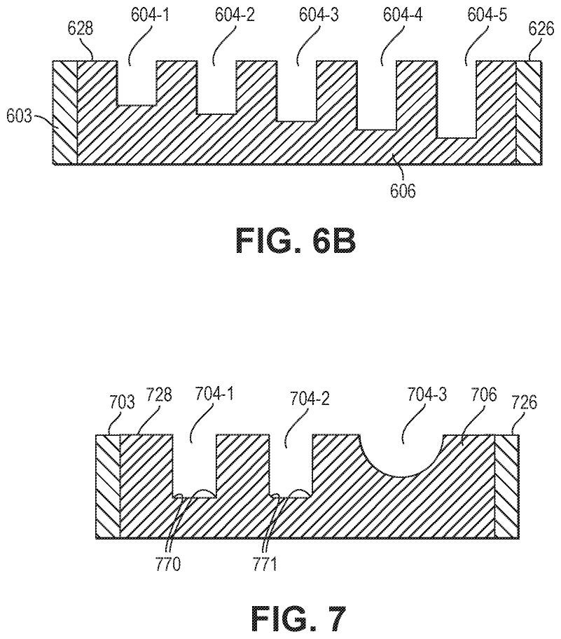

FIG. 6A illustrates a flow cell 606 in a planarizing pad 603 that can be planarizing pad 103, 203, 303, or 503 in accordance with a number of embodiments of the present disclosure. FIG. 6B is a cross-sectional view viewed along line 6B-6B of FIG. 6A in accordance with a number of embodiments of the present disclosure. In FIGS. 6A and 6B, flow cell 606 has flow channels 604-1 to 604-5. Flow cell 106, 206, or 306 or each of flow cells 506-1 to 506-4 can be flow cell 606. Flow channels 604-1 to 604-5 respectively extend to different levels (e.g., distances) below the upper surface 628 of flow cell 606. Upper surface 628 can be coplanar with an upper surface 626 of planarizing pad 603.

In various instances, planarizing pad 603 and flow cell 606 can wear over time. For example, planarizing pad 603 can be conditioned with an abrasive (e.g., diamond-coated) disk between planarization processes, and this can cause planarizing pad 603 and flow cell 606 to wear. As a result, the depths of flow channels 604-1 to 604-5 can be reduced to a point where they can no longer be used for determining the wettability of a surface of a rotating structure, such as rotating structure 102 or 502. This problem can be solved by having flow channels 604-1 to 604-5 respectively extending to different distances below upper surface 628.

Flow channels 604-1 to 604-5 can be respectively used based on the wear of flow cell 606. For example, flow channels 604-1 to 604-5 can be used (e.g., one at a time) in succession in response to the wear of flow cell 606. In some examples, the wear can be based on an elapsed time from when planarizing pad 603 was first put into to use. For example, flow channels 604-1 to 604-5 can be sequentially put into use at respective instants of time respectively measured from when planarizing pad 603 was first put into to use.

In the example of FIG. 6A, inlets to flow channels 604-1 to 604-5 can open into (e.g., can be fluidly coupled to) an injection manifold 666 that is common (e.g., commonly fluidly coupled) to (e.g., the inlets of) flow channels 604-1 to 604-5. Outlets of flow channels 604-1 to 604-5 can open into a drain manifold 668 that is common to (e.g., the outlets of) flow channels 604-1 to 604-5. A liquid injection port 630 and a gas injection port 633 can open into injection manifold 666 to respectively concurrently inject liquid and gas flows into injection manifold 666 that can concurrently inject a resulting liquid-gas flow into flow channels 604-1 to 604-5 while a rotating structure, such as rotating structure 102 or 502, is aligned with flow cell 606.

For example, liquid injection port 630 and a gas injection port 633 can be respectively fluidly coupled to liquid supply 112 and gas supply 113, for example, through flow passages in planarizing pad 603 (not shown in FIG. 6A). A drain port 635 can open into drain manifold 668 and can drain the liquid-gas flows in flow channels 604-1 to 604-5 to drain 114. For example, drain port 635 can be fluidly coupled to drain 114 through a flow passage in planarizing pad 603 (not shown in FIG. 6A). As such, liquid injection port 630 and gas injection port 633 can respectively form a liquid injection inlet and a gas injection inlet to flow channels 604-1 to 604-5, and drain port 635 can form a drain outlet from flow channels 604-1 to 604-5.

For the configuration of FIG. 6A, a two-phase liquid-gas flow can flow concurrently through the respective flow channels 604-1 to 604-5, and the respective two-phase liquid-gas flow in the respective flow channels 604-1 to 604-5 can be sensed one at a time based on the wear. For example, the sensing of the respective two-phase liquid-gas flow in the respective channels can commence at the respective instants of time such that the commencement of the sensing of a respective channel puts the respective channel into (e.g., selects the respective channel for) use. For example, a respective channel is in use as long as the respective channel is being sensed.

Alternatively, each of the respective flow channels 604-1 to 604-5 can be configured as described previously for flow channel 204 or 304 or a flow channel 504. For example, each of the respective flow channels 604-1 to 604-5 can be fed by a respective dedicated liquid injection port, such as liquid injection port 230, 330, or 530, and a respective dedicated gas injection port, such as gas injection port 233, 333, or 533, and drained by a respective dedicated drain port, such as drain port 235, 335, or 535. In such instances, for example, respective liquid injection valves can be configured to selectively fluidly couple the respective liquid injection ports (e.g., one at a time) to liquid supply 112; respective gas injection valves can be configured to selectively fluidly couple the respective gas injection ports (e.g., one at a time) to gas supply 113; and respective drain valves can be configured to selectively fluidly couple the respective drain ports (e.g., one at a time) to drain 114. In such examples, controller 115 can select a respective flow channel by activating the respective liquid injection valve, the respective gas injection valve, and the respective drain valve concurrently to produce a two-phase liquid-gas flow in the respective channel. The selected channel can then be sensed as described previously.

FIG. 7 is a cross-section of a planarizing pad 703 having a flow cell 706 with a group of flow channels 704-1 to 704-3 each with a different cross-sectional shape in accordance with a number of embodiments of the present disclosure. For example, flow channels 704-1 to 704-3 can extend into flow cell 706 from an upper surface 728 of flow cell 706 that can be coplanar with an upper surface 726 of planarizing pad 703. Flow cell 106, 206, or 306 or each of flow cells 506-1 to 506-4 can be a flow cell 706.

Flow channel 704-1 can have a rectangularly shaped cross-section with sharp bottom corners 770 (e.g., with corner radii of curvature of about zero). Flow channel 704-2 can have a rectangularly shaped cross-section with rounded bottom corners 771 (e.g., with corner radii of curvature of greater than bottom corners 770) that can act to improve flow characteristics (e.g., that can be easier to sense) relative to square corners 770. Flow channel 704-3 can semi-circular cross-section. However, the present disclosure is not limited to the cross-sectional shapes illustrated in FIG. 7. For example, in other embodiments, flow cells can have flow channels with, elliptical-shaped cross-sections, “U”-shaped cross-sections, among others. Flow channel 104, 204, 304, or 404 or each of flow channels 505 can be flow channel 704-1, 704-2, or 704-3. In various examples, flow channel 704-1 can be used in conjunction with laser scattering and/or image sensing with a camera, such as camera 244, 344, or 544, and flow channel 704-3 can be used in conjunction with laser scattering, laser refraction, and/or image sensing with a camera, such as camera 244, 344, or 544.

Flow channels 704-1 to 704-3 can have inlets that can open into an injection manifold, such as injection manifold 666, that is common to flow channels 704-1 to 704-3, and outlets of flow channels 704-1 to 704-3 can open into a drain manifold, such as drain manifold 668, that is common to flow channels 704-1 to 704-3. For example, as described previously, in conjunction with FIG. 6A, the injection manifold can inject a two-phase liquid-gas flow into flow channels 704-1 to 704-3 concurrently, and flow channels 704-1 to 704-3 can be sensed one at a time or concurrently.

Alternatively, each of the respective flow channels 704-1 to 704-3 can be configured as described previously for flow channel 204 or 304 or a flow channel 504. For example, each of the respective flow channels 704-1 to 704-3 can be fed by dedicated liquid injection port, such as a liquid injection port 230, 330, or 530, and a dedicated gas injection port, such as a gas injection port 233, 333, or 533, and drained by a dedicated drain port, such as drain port 235, 335, or 535. In such instances, for example, respective liquid injection valves can be configured to selectively fluidly couple the respective liquid injection ports (e.g., one at a time) to liquid supply 112; respective gas injection valves can be configured to selectively fluidly couple the respective gas injection ports (e.g., one at a time) to gas supply 113; and respective drain valves can be configured to selectively fluidly couple the respective drain ports (e.g., one at a time) to drain 114. In such examples, controller 115 can select a respective flow channel by activating the respective liquid injection valve, the respective gas injection valve, and the respective drain valve concurrently to produce a two-phase liquid-gas flow in the respective channel. The selected channel can then be sensed as described previously.

The term semiconductor can refer to, for example, a material, a wafer, or a substrate, and includes any base semiconductor structure. “Semiconductor” is to be understood as including silicon-on-sapphire (SOS) technology, silicon-on-insulator (SOI) technology, thin-film-transistor (TFT) technology, doped and undoped semiconductors, epitaxial silicon supported by a base semiconductor structure, as well as other semiconductor structures. Furthermore, when reference is made to a semiconductor in the preceding description, previous process steps may have been utilized to form regions/junctions in the base semiconductor structure, and the term semiconductor can include the underlying materials containing such regions/junctions.

In the preceding detailed description, reference is made to the accompanying drawings that form a part hereof, and in which is shown, by way of illustration, specific examples. In the drawings, like numerals describe substantially similar components throughout the several views. Other examples may be utilized, and structural, logical, mechanical, and/or electrical changes may be made without departing from the scope of the present disclosure.

The figures herein follow a numbering convention in which the first digit or digits correspond to the drawing figure number and the remaining digits identify an element or component in the drawing. Similar elements or components between different figures may be identified by the use of similar digits. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate the embodiments of the present disclosure and should not be taken in a limiting sense.

As used herein, “a,” “an,” or “a number of” something can refer to one or more of such things. A “plurality” of something intends two or more. As used herein, multiple acts being performed concurrently refers to acts overlapping, at least in part, over a particular time period. It should be recognized the term “perpendicular” takes into account variations from “exactly” perpendicular due to routine manufacturing and/or assembly variations and that one of ordinary skill in the art would know what is meant by the term “perpendicular.”

As used herein, the term “coupled” can include electrically coupled, fluidly coupled, directly coupled (e.g., directly connected) with no intervening elements (e.g., by direct physical contact), indirectly coupled (e.g., indirectly connected) with intervening elements, or wirelessly coupled. The term coupled can further include two or more elements that co-operate or interact with each other (e.g., as in a cause and effect relationship). As used herein, “fluidly coupled components” mean that the components are coupled such that a fluid (e.g., a gas, a liquid, etc.) can flow from (out of) one of the components and into another.

Although specific examples have been illustrated and described herein, those of ordinary skill in the art will appreciate that an arrangement calculated to achieve the same results can be substituted for the specific embodiments shown. This disclosure is intended to cover adaptations or variations of one or more embodiments of the present disclosure. It is to be understood that the above description has been made in an illustrative fashion, and not a restrictive one. The scope of one or more examples of the present disclosure should be determined with reference to the appended claims, along with the full range of equivalents to which such claims are entitled.

What is claimed is:

1. A method, comprising:
performing a planarization process on a structure by moving a pad against the structure, wherein the pad includes a flow cell formed therein;
producing a flow in the flow cell while a surface of the structure contacts the flow; and
determining an endpoint of the planarization process based on a determined characteristic change of the flow.

2. The method of claim 1, wherein the flow comprises a two-phase liquid-gas flow, and wherein the method includes stopping the planarization process in response to determining the endpoint.

3. The method of claim 1, wherein the characteristic change of the flow indicates a change in wettability of a surface of the structure.

4. The method of claim 1, wherein the endpoint corresponds to a first material being removed from the moving structure to expose a second material of the moving structure.

5. The method of claim 1, wherein the endpoint corresponds to a surface of the structure being polished to a particular finish.

6. The method of claim 1, further comprising determining the characteristic change of the flow by an optical sensing system or an acoustical sensing system.

7. The method of claim 1, wherein determining the characteristic change of the flow comprises determining that a reflectivity of the flow changes to a predetermined reflectivity, that a refractive index of the flow changes to a predetermined refractivity, a mean size of gas bubbles in the flow changes to a predetermined mean size, a mean distance between the gas bubbles in the flow changes to a predetermined mean distance, a gas void fraction of the flow changes to a predetermined gas void fraction, or an intensity of light scattered by the flow changes to a predetermined intensity.

8. A method, comprising:
rotating a pad against a rotating structure to remove a first material of the rotating structure from a second material of the rotating structure;
sensing a flow characteristic of a flow in a channel carried by the rotating pad while a surface of the rotating structure contacts the flow; and
determining whether the first material is removed from the second material based on the sensed flow characteristic.

9. The method of claim 8, further comprising determining that the first material is removed from the second material in response to determining that the sensed flow characteristic changes to a predetermined flow characteristic.

10. The method of claim 9, wherein the sensed flow characteristic changes to the predetermined flow characteristic in response to a change in wettability of the surface of the rotating structure as a result of the removal of the first material from the second material.

11. The method of claim 8, wherein surface of the rotating object contacts the flow during a portion of a rotation period of the pad.

12. An apparatus, comprising:
a planarizing pad comprising a flow cell;
wherein the flow cell comprises:
a flow channel extending into the flow cell from an upper surface of the flow cell;
a first injection port forming a first inlet to the flow channel;
a second injection port forming a second inlet to the flow channel; and
a drain port forming an outlet of the flow channel.

13. The apparatus of claim 12, wherein the channel is configured to be closed by a moving structure moving against the planarizing pad as the planarizing pad moves.

14. The apparatus of claim 13, wherein the flow channel is configured to carry, while the flow channel is closed by the moving structure, a two-phase liquid-gas flow created by concurrently injecting liquid and gas, respectively by the first and second injection ports, into the flow channel.

15. The apparatus of claim 12, wherein the flow cell is optically transparent.

16. The apparatus of claim 12, wherein the upper surface of flow cell is coplanar with an upper surface of the planarizing pad.

17. The apparatus of claim 12, wherein
the flow passage is one of a plurality of flow channels extending into the flow cell from the upper surface of the flow cell; and
each of the flow channels of the plurality of flow channels extends into the flow cell from the upper surface of the flow cell by a different distance than each remaining flow channel of the plurality of flow channels.

18. The apparatus of claim 17, wherein:
the first injection port forms a liquid injection inlet to the plurality of flow channels;
the second injection port forms a gas injection inlet to the plurality of flow channels; and
the drain port forms a drain outlet from the plurality of flow channels.

19. The apparatus of claim 12, wherein the flow passage comprises square corners, rounded corners, or a semicircular cross-section.

20. The apparatus of claim 12, wherein
the flow passage is one of a plurality of flow channels extending into the flow cell from the upper surface of the flow cell; and
each of the plurality of flow channels comprises a different cross-sectional shape.

21. A system, comprising:
a planarizing pad comprising a flow cell;
a gas supply fluidly coupled to the flow cell;
a liquid supply fluidly coupled to the flow cell;
a carrier configured to move a structure against the planarizing pad while the planarizing pad is moving during a planarization process;
wherein
the gas and liquid supply are configured to produce a flow in the flow cell; and
the flow is configured to indicate an endpoint of the planarization process in response to a change in wettability of a surface of the moving structure while the surface of the moving structure is in contact with the flow.

22. The system of claim 21, further comprising:
a sensing system configured to sense the endpoint by sensing a change in a characteristic of the of the flow;
wherein the change in the characteristic of the of the flow is in response to the change in the wettability of the surface of the moving structure.

23. The system of claim 22, further comprising a processor coupled to the sensing system and configured to determine the change in the characteristic of the flow from a signal received from the sensing system.

24. The system of claim 22, wherein the sensing system is located in a platen that is configured to move the planarizing pad.

25. The system of claim 22, wherein the sensing system comprises:
an electromagnetic radiation source configured to irradiate the flow; and
an electromagnetic radiation detector configured to detect electromagnetic radiation received from the irradiated the flow.

26. The system of claim 22, wherein the sensing system comprises at least one of:
an image capturing device and an acoustic sensing system.
